(19) United States
(12) Patent Application Publication
(10) Pub. No.: US 2005/0239237 A1
(43) Pub. Date: Oct. 27, 2005

(54) Method for producing a BGA chip module and BGA chip module

(75) Inventors: Frank Puschner, Kelheim (DE); Wolfgang Schindler, Regenstauf (DE); Gunter Tutsch, Saal/Do. (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/112,739

(22) Filed: Apr. 22, 2005

(30) Foreign Application Priority Data
Apr. 27, 2004 (DE) 10 2004 020 580.9

(51) Int. Cl. H01L 21/44; H01L 21/48; H01L 21/50

(52) U.S. Cl. 438/125

(57) ABSTRACT

BGA chip module and method for producing the BGA chip module by providing a carrier, forming holes at points at which bonding points of the BGA chip module are to be produced, forming metallization areas on an upper side of the carrier and covering the holes, connecting bonding points of a chip to the metallization areas, and introducing bonding elements into the holes.

### CROSS-REFERENCE TO RELATED APPLICATION

This application claims priority to German Patent Application Serial No. 102004020580.9, filed Apr. 27, 2004, and which is incorporated herein by reference in its entirety.

### FIELD OF THE INVENTION

The invention relates to a method for producing a BGA chip module. The invention also relates to a BGA chip module with a carrier, a chip arranged on an upper side of the carrier and bonding points on the underside of the carrier.

### BACKGROUND OF THE INVENTION

BGA stands for Ball Grid Array and refers to chip modules which have their bonding points arranged in the form of a grid on the underside of the module. It is customary for example to provide 64 bonding points in a grid spacing of 1.5 mm, 1.27 mm or 1 mm with a diameter of the “balls” of about 0.6 mm.

BGA chip modules of this type are known from, for example, the textbook by Wolfgang Scheel (editor): Baugruppentechnologie der Elektrotechnik, Verlag Technik, Berlin, first edition 1997. The chip, the term chip being used for integrated circuits, is mounted in a standard package. The bonding points of the chip must be connected to bonding points on the underside of the module during the production of a BGA chip module. It is known to use a carrier which has via holes, through which chip terminals are connected to terminal pads on the underside of the module. Solder balls are applied to the terminal pads of the underside, so that the terminal pads can later be connected to a printed circuit board.

The disadvantage of this method is that generally expensive, multilayered printed circuit boards have to be used, in particular if there are relatively great requirements for reliability, for example relatively great thermal or thermomechanical loads are to be withstood without damage. This makes BGA chip modules of this type expensive, since many wiring interposers and via holes are required to lead the terminals to the correct point.

### SUMMARY OF THE INVENTION

An object of the invention is to provide a method for producing a BGA chip module which is less expensive to produce. Furthermore, a BGA chip module which can be produced at low cost is to be provided.

This object is achieved by a method for producing a BGA chip module with the steps of providing a carrier, forming holes at points of the carrier at which bonding points of the BGA chip module are to be produced, forming metallization areas on an upper side of the carrier and covering the holes, connecting bonding points of a chip to the metallization areas, and introducing bonding elements into the holes.

With respect to the chip module, the object is achieved by a BGA chip module of the type stated at the beginning, wherein the carrier has through-holes, which are covered on the upper side by metallization areas, the metallization areas being electrically connected to bonding points of the chip and bonding elements being accommodated in the holes.

### BRIEF DESCRIPTION OF THE DRAWINGS

The invention is explained in more detail below on the basis of an exemplary embodiment. In the drawings:

FIG. 1 shows a cross section through a BGA chip module according to an exemplary embodiment of the invention in a schematic representation;

FIG. 2 shows a plan view of the bonding side of the BGA chip module according to the exemplary embodiment of the invention; and

FIG. 3 shows an arrangement of a number of BGA chip modules according to the exemplary embodiment of the invention in a continuous carrier strip 13.

### DETAILED DESCRIPTION OF PREFERRED EMBODIMENTS OF THE INVENTION

An advantage of the method according to an exemplary embodiment of the invention is that the forming of holes in a carrier can be implemented very inexpensively, for example by punching. The application of metallization areas is likewise a low-cost production step. The same applies to the introduction of bonding elements into the holes from the underside of the carrier. Consequently, the overall method comprises low-cost production steps using low-cost starting materials. In comparison with the method according to the prior art, it dispenses with the use of expensive multilayered printed circuit boards which have via holes. It likewise dispenses with the method step of applying terminal pads. These are replaced by the bonding elements which are fitted into the holes.

In an advantageous embodiment, the bonding elements are solder balls. These are of such a size that on the one hand they touch the metallization areas arranged on the upper side of the carrier and on the other hand they protrude beyond the surface of the underside, in order in this way to form the “balls” of the ball grid array.

It is also inexpensive to use an epoxy film as the carrier. This costs little and is easy to process. The method steps and machines required for this are known from the production of chip card modules and therefore do not present any technological problems.

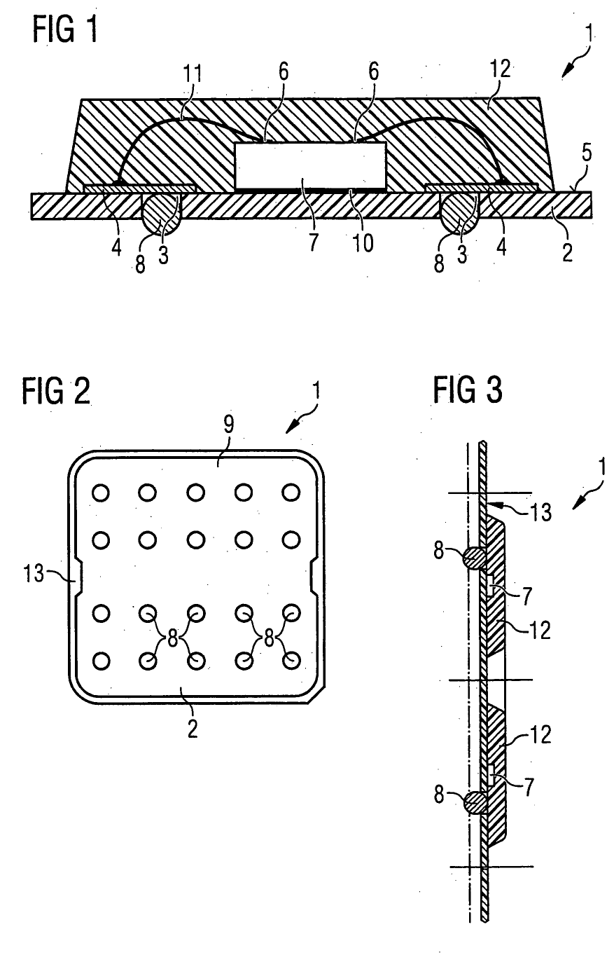

FIG. 1 shows a BGA chip module according to an exemplary embodiment of the invention, which is produced by using a method according to the invention. A number of holes 3 are formed in a carrier film 2 by punching. On an upper side 5 of the carrier film 2, metallization areas 4 are provided such that they cover over the holes 3. The material and the geometrical configuration of the bonding areas 4 are chosen such that bonding points 6 of a chip 7, which is likewise arranged on the carrier film 2, can be electrically connected to the bonding areas 4 by means of connecting wires 11. The bonding areas 4 must therefore be arranged such that wire connections can be led from the chip 7 to the bonding areas 4 without the wires coming into contact with other wires. The chip 7 is connected to the carrier film 2 by means of an adhesive layer 10 and is thereby securely held during assembly.

The holes have been formed at points at which there are later intended to be bonding points of the finished BGA chip module 1. The metallization areas 4 therefore have, if need be, the form of interconnects, in order to allow on the one hand bonding at a favorable point and on the other hand provision of the bonding points of the BGA chip module at the specified point.

After the forming of the metallization areas 4, the holes 3 are closed on the upper side 5 of the carrier film 2. Solder balls 8 are then fitted from the underside 9, and are connected to the underside of the metallization areas 4 in the plane of the upper side of the carrier film 2. The size of the solder balls 8 is made to match the thickness of the carrier film 2 such that the solder balls 8 protrude beyond the underside 9 and so form “balls” of the “ball grid array”. There is later the possibility of mounting the finished BGA chip module 1 on a printed circuit board and connecting it to the latter mechanically and electrically by melting of the solder balls 8.

On the upper side 5 of the carrier film 2, the arrangement enclosing the chip 7 is provided with a covering layer 12, which is formed for example by injection molding or as a glob top.

The embodiment represented is a carrier film 2 with metallization on one side. However, it is also within the scope of the invention to use a carrier film 2 with metallization on both sides, if this is necessary to provide further connection possibilities.

In the exemplary embodiment shown in FIG. 1, the semiconductor chip is connected to the metallization areas 4 by means of wire bonding. In another embodiment of the invention, which is not represented in the figures, a chip is connected to the metallization areas by what is known as the flip-chip technique. This involves placing the chip on the metallization areas 4 with the side having the bonding points. Of course, additional measures have to be provided in order that the bonding areas of the chip can be connected to the corresponding mating contact areas. Solder bumps are suitable for this, so that a mechanical and electrical connection to the metallization areas 4 is automatically created when the solder bumps are melted.

FIG. 2 shows a plan view of the underside 9 of a BGA chip module 1. In the example shown, ten bonding elements 8 are provided in a symmetrical arrangement.

The BGA chip module 1 is still in a carrier strip 13, so that it still has to be singulated by punching out.

FIG. 3 shows two BGA chip modules 1, which are still connected to one another in a carrier strip 13. The singulating of the BGA chip modules can be performed by punching out; however, a perforation could also be provided around the chip modules, so that it is possible to accomplish singulation by pressing the modules out.

As is evident from the use of a carrier strip, a customary reel-to-reel process can be used for the production of the BGA chip modules 1 according to the invention.

1. A method for producing a BGA chip module comprising the steps of:
providing a carrier;
forming holes at points at which bonding points of the BGA chip module are to be produced;
forming metallization areas on an upper side of the carrier and covering the holes;
connecting bonding points of a chip to the metallization areas; and
introducing bonding elements into the holes.

2. The method of claim 1, wherein the bonding elements are solder balls.

3. The method of claim 1, wherein the carrier is an epoxy film.

4. The method of claim 1, wherein the holes are formed by punching.

5. The method of claim 1, wherein the chip is electrically connected to the metallization areas by wire bonding.

6. The method of claim 1, wherein the chip is electrically connected to the metallization areas by a flip-chip technique.

7. The method of claim 1, further comprising the step of connecting the chip to the carrier by means of an adhesive layer.

8. The method of claim 2, wherein the size of the solder balls corresponds with the thickness of the carrier such that the solder balls protrude beyond the underside of the carrier.

9. The method of claim 1, further comprising the step of enclosing the chip with a covering layer.

10. The method of claim 9, wherein the covering layer is formed by injection molding or as a glob top.

11. The method of claim 1, further comprising the step of forming metallization areas on an underside of the carrier.

12. The method of claim 1, wherein the bonding elements are provided in a symmetrical arrangement.

13. The method of claim 1, wherein the BGA chip module is formed in a carrier strip.

14. The method of claim 13, further comprising the step of singulating the BGA chip module by punching out.

15. The method of claim 13, further comprising the step of providing perforations around the BGA chip module.

16. A BGA chip module comprising:
a carrier having through-holes;
a chip arranged on an upper side of the carrier;
bonding points arranged on the underside of the carrier;
metallization areas covering the through-holes on the upper side of the carrier and being electrically connected to bonding points; and
bonding elements accommodated in the through-holes.

17. The BGA chip module of claim 16, wherein the bonding elements are solder balls.

18. The BGA chip module of claim 16, wherein the carrier is an epoxy film.

19. The BGA chip module of claim 16, wherein the chip is electrically connected to the metallization areas by connecting wires.

20. The BGA chip module of claim 16, wherein the chip is electrically connected to the metallization areas by a flip-chip technique.

21. The BGA chip module of claim 16, wherein the chip is connected to the carrier by means of an adhesive layer.

22. The BGA chip module of claim 17, wherein the size of the solder balls corresponds with the thickness of the carrier such that the solder balls protrude beyond the underside of the carrier.

23. The BGA chip module of claim 16, further comprising a covering layer enclosing the chip.

24. The BGA chip module of claim 23, wherein the covering layer is formed by injection molding or as a glob top.

25. The BGA chip module of claim 16, further comprising metallization areas formed on an underside of the carrier.

26. The BGA chip module of claim 16, wherein the bonding elements are provided in a symmetrical arrangement.

27. The BGA chip module of claim 16, wherein the BGA chip module is formed in a carrier strip.

28. The BGA chip module of claim 27, wherein the BGA chip is singulated by punching out.

29. The BGA chip module of claim 16, further comprising perforations formed around the BGA chip module.

30. A BGA chip module comprising:
a carrier;
holes formed at points at which bonding points of the BGA chip module are to be produced;
metallization areas formed on an upper side of the carrier and covering the holes;
means for connecting a chip to the metallization areas; and
second bonding means accommodated in the holes.

31. The BGA chip module of claim 30, further comprising means for connecting the chip to the carrier.

32. The BGA chip module of claim 30, further comprising means for covering the chip.
